(19) United States
(12) Patent Application Publication
(10) Pub. No.: US 2026/0166847 A1
(43) Pub. Date: Jun. 18, 2026

(54) BONDING FILM AND METHOD FOR PRODUCING BONDING FILM

(71) Applicant: Resonac Corporation, Minato-ku, Tokyo (JP)

(72) Inventors: Koichi CHABANA, Minato-ku, Tokyo (JP); Tomonori HARADA, Minato-ku, Tokyo (JP); Jun OKAYAMA, Minato-ku, Tokyo (JP)

(21) Appl. No.: 18/855,323

(22) PCT Filed: Mar. 6, 2024
(86) PCT No.: PCT/JP2024/008552

§ 371 Date: Oct. 9, 2024

(30) Foreign Application Priority Data
Apr. 19, 2023 (JP) 2023-068610

(51) Int. Cl. B32B 7/12; B32B 27/08

(52) U.S. Cl. CPC B32B 7/12; B32B 27/08

(57) ABSTRACT

A bonding film includes a plurality of functional layers including a bonding layer and an adhesive film and arranged apart from one another in an extending direction of a substrate film, and a plurality of protective layers including the bonding layer and the adhesive film and arranged symmetrically with respect to a width direction of the substrate film so as to surround the functional layers. The functional layer has a circular shape in plan view of the substrate film. The protective layer includes a straight line portion extending along the extending direction of the substrate film, and a straight line portion facing a circumference of the functional layer, in plan view of the substrate film.

### TECHNICAL FIELD

The present disclosure relates to a bonding film, and a method for producing a bonding film.

### BACKGROUND ART

Conventional bonding films include, for example, a die attachment laminated sheet support disclosed in Patent Literature 1. The conventional die attachment laminated sheet support includes a long substrate film, and a plurality of die attachment laminated films dispersedly arranged in a length direction of the substrate film on one surface of the substrate sheet.

The die attachment laminated film includes a die attachment film on the substrate film side, and a dicing film on the die attachment film. On one surface of the substrate film, protective films identical in thickness to the die attachment laminated film are arranged so as to surround the respective die attachment laminated films. By the arrangement of the protective film, for example, the die attachment laminated film can be protected from a pressure in winding of the bonding film in a roll shape, so that it is possible to suppress occurrence of deformation of the laminated film, transfer of winding impressions, and the like.

### CITATION LIST

### Patent Literature

Patent Literature 1: Japanese Unexamined Patent Publication No. 2006-202927

### SUMMARY OF INVENTION

### Technical Problem

For production of the bonding film described above, for example, a roll-to-roll method is used. In this method, a substrate film including a bonding layer on one surface thereof is unwound from an unprocessed film roll, and an adhesive film is laminated to the bonding layer. Thereafter, the bonding layer and the adhesive film on the substrate film are pre-cut in a predetermined pattern with a roll blade. After the pre-cutting, an unnecessary portion of the bonding layer and the adhesive film is peeled from the substrate film to form a functional layer including the bonding layer and the adhesive film and a protective layer surrounding the functional layer on one surface of the substrate film.

However, in the process of producing such a bonding film, depending on a shape in which the bonding layer and the adhesive film are pre-cut, defects such as breakage and chipping may occur in an unnecessary portion of the bonding layer and the adhesive film in peeling of the unnecessary portion. If such defects occur, it may be impossible to peel the unnecessary portion while winding the bonding film at a constant conveyance rate, leading to a decrease in efficiency of production of the bonding film.

The present disclosure has been made to solve the above-described problems, and an object of the present disclosure is to provide a bonding film and a method for producing a bonding film, which enable suppression of breakage and chipping of an unnecessary portion even when the unnecessary portion is peeled while the film is wound at a constant conveyance rate, so that production efficiency is improved.

### Solution to Problem

A bonding film according to an aspect of the present disclosure includes: a long substrate film; and a bonding layer and an adhesive film provided on one surface of the substrate film. One surface of the substrate film is provided with a plurality of functional layers including the bonding layer and the adhesive film and arranged apart from one another in an extending direction of the substrate film, and a plurality of protective layers including the bonding layer and the adhesive film and arranged symmetrically with respect to a width direction of the substrate film so as to surround the functional layers. The functional layer has a circular shape in plan view of the substrate film. The protective layer includes a straight line portion extending along the extending direction of the substrate film, and a straight line portion facing a circumference of the functional layer, in plan view of the substrate film.

In the bonding film, the protective layer includes a straight line portion extending along the extending direction of the substrate film, and a straight line portion facing the circumference of the functional layer, in plan view of the substrate film. This configuration ensures that in comparison with a case where the protective layer extends along the circumference of the functional layer, the area of an unnecessary portion of the bonding layer and the adhesive film can be secured, and the shape of the unnecessary portion can include the straight line portion. This enables equalization of a force affecting the unnecessary portion in peeling from one surface of the substrate film, so that it is possible to suppress occurrence of defects such as breakage and chipping in the unnecessary portion even when the unnecessary portion is peeled while the bonding film is wound at a constant conveyance rate. The bonding film is continuously wound at a constant conveyance rate without occurrence of defects to improve production efficiency.

The protective layer may include an island-shaped portion having a triangular shape in plan view of the substrate film, and may be arranged such that an oblique side of the island-shaped portion faces the circumference of the functional layer and a base of the island-shaped portion faces an end part of the substrate film in the width direction. This configuration enables the protective layer to be efficiently arranged on the periphery of the functional layer. Therefore, the functional layer can be firmly protected from a pressure in winding of the bonding film in a roll shape, so that it is possible to suppress occurrence of deformation of the functional layer, transfer of winding impressions, and the like. In addition, the use of the straight line portion of the island-shaped portion enables the straight line portion to be sufficiently formed in the shape of the unnecessary portion of the bonding layer and the adhesive film. This ensures that a force affecting the unnecessary portion in peeling from one surface of the substrate film can be more reliably equalized.

The protective layer may include an island-shaped portion having a trapezoidal shape in plan view of the substrate film, and may be arranged such that an oblique side of the island-shaped portion faces the circumference of the functional layer and a lower base of the island-shaped portion faces an end part of the substrate film in a width direction. This configuration enables the protective layer to be efficiently arranged on the periphery of the functional layer. Therefore, the functional layer can be firmly protected from a pressure in winding of the bonding film in a roll shape, so that it is possible to suppress occurrence of deformation of the functional layer, transfer of winding impressions, and the like. In addition, the use of the straight line portion of the island-shaped portion enables the straight line portion to be sufficiently formed in the shape of the unnecessary portion of the bonding layer and the adhesive film. This ensures that a force affecting the unnecessary portion in peeling from one surface of the substrate film can be more reliably equalized.

The protective layer may include a belt-shaped portion extending in the extending direction of the substrate film at both end parts of the substrate film in the width direction. By arranging the protective layer at both end parts of the substrate film in the width direction, the functional layer can be more sufficiently protected from a pressure in winding of the bonding film in a roll shape. In addition, using the straight line portion of the belt-shaped portion, the straight line portion can be more sufficiently formed in the shape of the unnecessary portion of the bonding layer and the adhesive film. This ensures that a force affecting the unnecessary portion in peeling from one surface of the substrate film can be more reliably equalized.

A method for producing a bonding film according to an aspect of the present disclosure includes: an unwinding step of unwinding a long substrate film with a bonding layer provided on one surface thereof at a predetermined conveyance rate; a lamination step of laminating an adhesive film to the bonding layer; a cutting step of pre-cutting the bonding layer and the adhesive film in a predetermined pattern; a peeling step of peeling an unnecessary portion of the bonding layer and the adhesive film from one surface of the substrate film, and forming, on one surface of the substrate film, a plurality of functional layers arranged apart from one another in an extending direction of the substrate film, and a plurality of protective layers arranged symmetrically with respect to a width direction of the substrate film so as to surround the functional layers; and a winding step of winding the bonding film obtained in the peeling step in a roll shape. In the cutting step, the bonding layer and the adhesive film are pre-cut so that the functional layer has a circular shape in plan view of the substrate film, and the protective layer includes a straight line portion extending along the extending direction of the substrate film and a straight line portion facing a circumference of the functional layer in plan view of the substrate film.

In the method for producing a bonding film, a straight line portion extending along the extending direction of the substrate film and a straight line portion facing the circumference of the functional layer are formed on the protective layer in pre-cutting of the bonding layer and the adhesive film. This configuration ensures that in comparison with a case where the protective layer extends along the circumference of the functional layer, the area of an unnecessary portion of the bonding layer and the adhesive film can be secured, and the shape of the unnecessary portion can include the straight line portion. A force affecting the unnecessary portion in peeling from one surface of the substrate film can be equalized, so that it is possible to suppress occurrence of defects such as breakage and chipping in the unnecessary portion even when the unnecessary portion is peeled while the bonding film is wound at a constant conveyance rate. The bonding film is continuously wound at a constant conveyance rate without occurrence of defects to improve production efficiency.

### Advantageous Effects of Invention

According to the present disclosure, breakage and chipping of an unnecessary portion can be suppressed even when the unnecessary portion is peeled while the film is wound at a constant conveyance rate, so that production efficiency is improved.

### BRIEF DESCRIPTION OF DRAWINGS

FIG. 1 is a perspective view showing a bonding film according to an embodiment of the present disclosure.

FIG. 2 is a plan view of the bonding film shown in FIG. 1.

FIG. 3 is a sectional view taken along line III-III in FIG. 2.

FIG. 4 is a flowchart showing a method for producing a bonding film according to an embodiment of the present disclosure.

FIG. 5 is a perspective view showing a state of a peeling step.

FIG. 6 is a plan view showing a bonding film according to a modification.

FIG. 7 is a plan view showing a bonding film according to another modification.

FIG. 8 is a plan view showing a bonding film according to still another modification.

### DESCRIPTION OF EMBODIMENTS

Hereinafter, a bonding film and a method for producing a bonding film according to an aspect of the present disclosure will be described in detail with reference to the drawings.

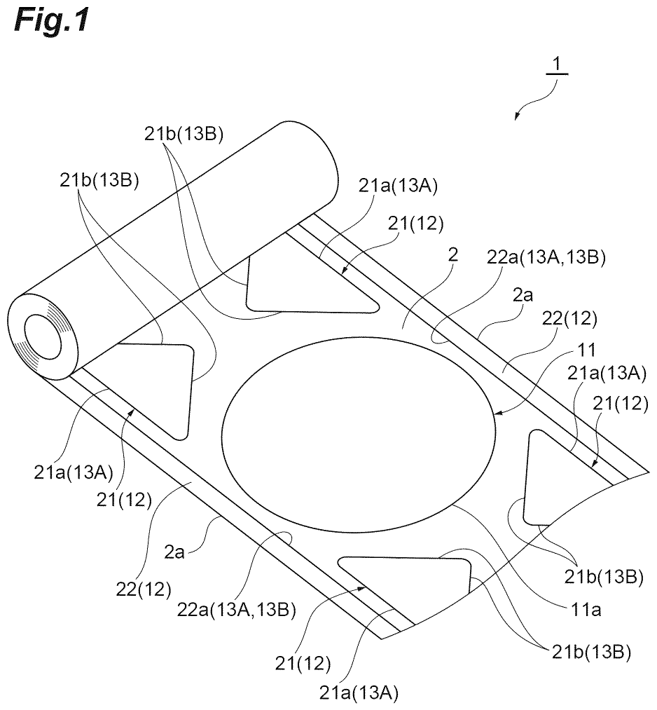

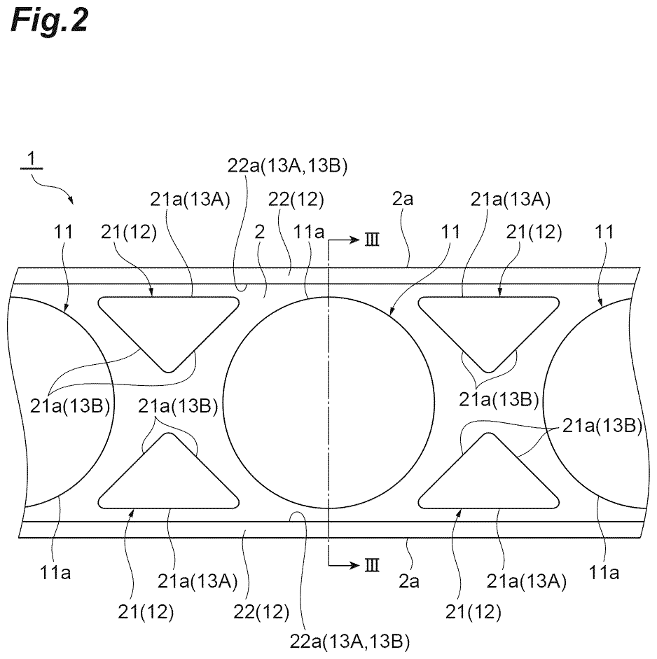

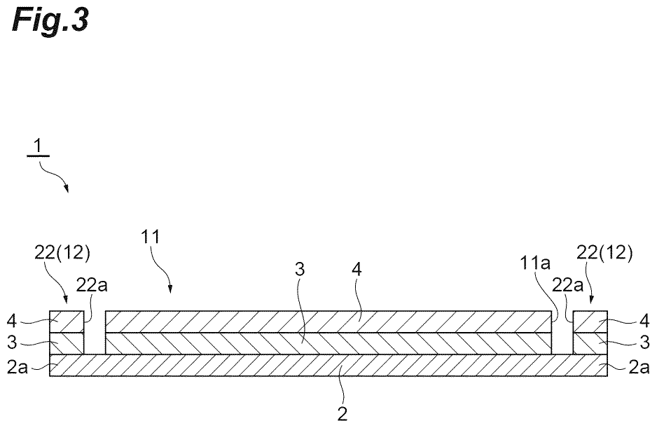

FIG. 1 is a perspective view showing a bonding film according to an embodiment of the present disclosure. FIG. 2 is a plan view of the bonding film shown in FIG. 1. FIG. 3 is a sectional view taken along line III-III in FIG. 2. A bonding film 1 shown in FIGS. 1 to 3 is used, for example, in a process of producing a semiconductor chip. The bonding film 1 is used, for example, for fixing a semiconductor wafer in a back grinding process or for bonding a semiconductor chip and a wafer in a bonding process. The bonding film 1 is stored in a state of being wound in a roll shape except when it is used (see FIG. 1).

As shown in FIGS. 1 to 3, the bonding film 1 includes a long substrate film 2, and a bonding layer 3, and an adhesive film 4 provided on one surface of the substrate film 2 (see FIG. 3). As shown in FIG. 3, the bonding layer 3 is disposed on the substrate film 2, and the adhesive film 4 is disposed on the bonding layer 3. The adhesive film 4 includes a substrate film and an adhesive layer, and is disposed on the bonding layer 3 with the adhesive layer facing the bonding layer 3 side (not shown).

The substrate film 2 is a film-shaped portion that forms a base of the bonding film 1. Examples of the constituent material for the substrate film 2 include polyethylene terephthalate, and include poly-semi-aromatic ester films such as polybutylene terephthalate and polyethylene naphthalate, wholly aromatic polyester films, liquid-crystalline aromatic polyester films, polyamide films, polyimide films, and polyamideimide films. A surface of the substrate film 2 may be subjected to mold release treatment with silicone or the like.

The bonding layer 3 is, for example, a film-shaped portion referred to as NCF (Non Conductive Film). Examples of the constituent material for the bonding layer 3 include thermosetting resins having an electrical insulation property. Examples of the thermosetting resin include epoxy resins, bismaleimide resins, triazine resins, polyimide resins, polyamide resins, cyanoacrylate resins, phenol resins, unsaturated polyester resins, melamine resins, urea resins, polyurethane resins, polyisocyanate resins, furan resins, resorcinol resins, xylene resins, benzoguanamine resins, diallyl phthalate resins, silicone resins, polyvinyl butyral resins, siloxane-modified epoxy resins, siloxane-modified polyamideimide resins, and acrylate resins. These can be used alone, or as a mixture of two or more thereof.

The adhesive film 4 is, for example, a film-shaped portion referred to as a back grinding tape. The adhesive film 4 may include one or more adhesive layers and one or more substrate films, or may include one adhesive layer and one substrate film. The thickness of the adhesive film 4 may be, for example, 10 μm to 200 μm, or 20 μm to 150 μm.

Examples of the substrate layer include plastic films such as polyester films, polytetrafluoroethylene films, polyethylene films, polypropylene films and polymethylpentene films. Among them, polyester films are preferable, and polyethylene terephthalate films are more preferable. The substrate layer may be a mixture of two or more selected from the above-described materials, or a layer obtained by combining any of the above-described films. The thickness of the substrate layer may be, for example, 10 μm to 100 μm, or 20 μm to 80 μm.

It is preferable that the adhesive layer has adhesive strength at room temperature, and has necessary adhesion strength to an adherend. The adhesive layer preferably has a property of being cured (made less adhesive) by a high energy ray such as radiation, or heat, and more preferably can be easily peeled from the bonding film 1 without applying a high energy ray such as radiation, or heat. The adhesive layer may be a pressure-sensitive adhesive layer. The adhesive layer can be formed using, for example, an acrylic resin, any of various kinds of synthetic rubber, natural rubber, or a polyimide resin. The thickness of the adhesive layer may be, for example, 5 μm to 100 μm, or 10 μm to 80 μm.

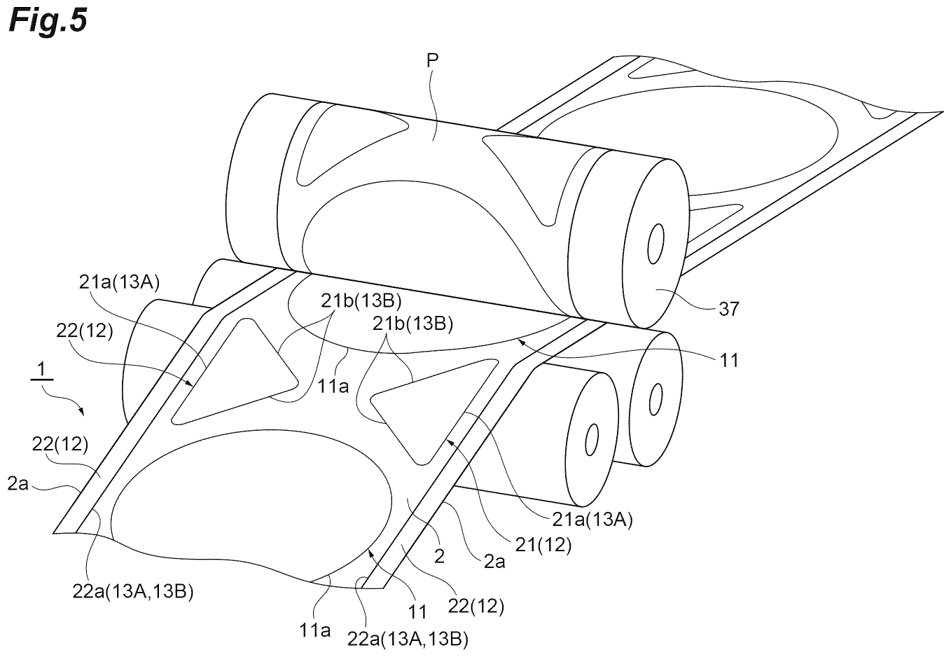

As shown in FIG. 2, the bonding layer 3 and the adhesive film 4 are separated into a plurality of functional layers 11 and a plurality of protective layers 12 by pre-cutting in advance. Each of the functional layer 11 and the protective layer 12 is a laminate of the bonding layer 3 and the adhesive film 4. Peeling of an unnecessary portion P described later leads to separation between a plurality of functional layers 11, 11, between a plurality of protective layers 12, 12, and between the functional layer 11 and the protective layer 12. Separation portions are formed by winding the unnecessary portion P using a peel roll (see FIG. 5), and therefore connected in the extending direction of the substrate film 2. In the separated portion, the bonding layer 3 and the adhesive film 4 are removed, and one surface of the substrate film 2 is exposed.

The functional layer 11 is a portion that is used in a process of producing semiconductor chips. As shown in FIG. 2, the functional layers 11 each have a perfectly circular shape in plan view of the substrate film 2, and are arranged apart from one another in the extending direction of the substrate film 2. The planar shape of the functional layer 11 is not necessarily a perfectly circular shape, and may be another form of a circular shape such as an elliptical shape or an oval shape. In the functional layer 11, a marker (not shown) may be added at a predetermined location on the adhesive film 4. The marker can be formed using, for example, a screen printing method, a stamping method, an ink-jet method, or the like.

The protective layer 12 is a portion that protects the functional layer 11 from a pressure in winding of the bonding film 1 in a roll shape. As shown in FIG. 2, the protective layers 12 are arranged symmetrically with respect to the width direction of the substrate film 2 so as to surround the respective functional layers 11. In the present embodiment, the protective layers 12 are arranged between the functional layers 11, 11 adjacent in the extending direction of the substrate film 2, where the protective layers 12 are paired while the center of the substrate film 2 in the width direction is interposed therebetween.

The protective layer 12 includes a straight line portion 13A extending along the extending direction of the substrate film 2, and a straight line portion 13B facing a circumference 11a of the functional layer 11, in plan view of the substrate film 2. The straight line portion 13A extends parallel to the extending direction of substrate film 2. A slight angular deviation with respect to the extending direction of the substrate film 2 can be allowed. The phrase “facing the circumference 11a of the functional layer 11” in the straight line portion 13B means that an imaginary straight line orthogonally crossing the straight line portion 13B crosses the circumference 11a of the functional layer 11. The imaginary straight line orthogonally crossing the straight line portion 13B does not necessarily cross the circumference 11a of the functional layer 11 throughout the straight line portion 13B, and is only required to cross the circumference 11a of the functional layer 11 in at least a part of the straight line portion 13B.

The diameter of the functional layer 11 may be, for example, 295 mm to 310 mm, or 298 mm to 305 mm. The width of the substrate film 2 (the length of the substrate film in a direction orthogonally crossing the extending direction thereof) is not particularly limited as long as it is equal to or larger than the diameter of the functional layer 11 and the width of a belt-shaped portion 22 described later. The width of the substrate film 2 may be, for example, 320 mm to 400 mm, or 330 mm to 350 mm.

In formation of the straight line portions 13A, 13B, in the example of FIG. 2, the protective layer 12 includes an island-shaped portion 21 having a triangular shape in plan view of the substrate film 2, and the belt-shaped portion 22 extending in the extending direction of the substrate film 2 at both end parts 2a, 2a of the substrate film 2 in the width direction. The planar shape of the island-shaped portion 21 is, for example, an isosceles triangle shape. The planar shape of the island-shaped portion 21 may be an isosceles right triangle shape or an equilateral triangle shape. The corners of the island-shaped portion 21 may have a rounded shape. The island-shaped portion 21 is arranged with its apex angle facing the center of the substrate film 2 in the width direction. A base 21a of the island-shaped portion 21 corresponds to the straight line portion 13A extending along the extending direction of the substrate film 2, and faces the end part 2a of the substrate film 2 in the width direction and an inner edge 22a of the belt-shaped portion 22. An oblique side 21b of the island-shaped portion 21 corresponds to the straight line portion 13B facing the circumference 11a of the functional layer 11.

The belt-shaped portion 22 is arranged with a predetermined width from an edge of the substrate film 2 in the width direction. The belt-shaped portion 22 extends over the entire length of the substrate film 2 in the extending direction. The inner edge 22a of the belt-shaped portion 22 corresponds to the straight line portion 13A extending along the extending direction of the substrate film 2. A portion of the inner edge 22a of the belt-shaped portion 22, in which the imaginary straight line orthogonally crossing the inner edge 22a crosses the circumference 11a of the functional layer 11, corresponds to the straight line portion 13B facing the circumference 11a of the functional layer 11. That is, the inner edge 22a of the belt-shaped portion 22 are present as both the straight line portions 13A, 13B.

Next, a method for producing the bonding sheet will be described.

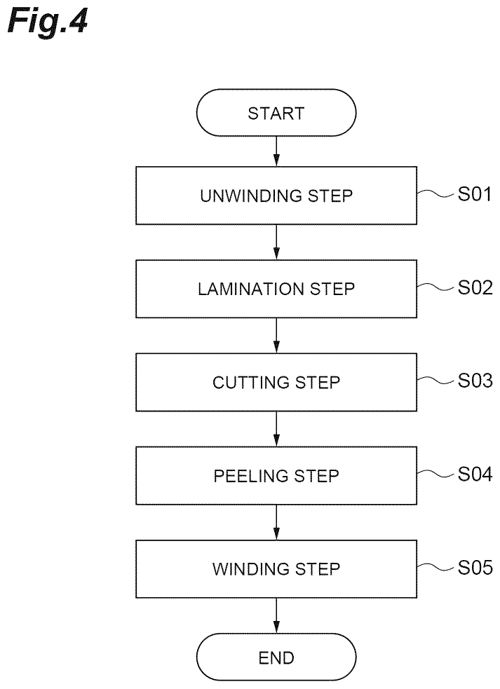

FIG. 4 is a flowchart showing a method for producing a bonding film according to an embodiment of the present disclosure. As shown in the drawing, the method for bonding film includes an unwinding step (step S01), a lamination step (step S02), a cutting step (step S03), a peeling step (step S04), and a winding step (step S05).

The unwinding step S01 is a step of unwinding the long substrate film 2 with the bonding layer 3 provided on one surface thereof at a predetermined conveyance rate. The lamination step S02 is a step of laminating the adhesive film 4 to the bonding layer 3. The cutting step S03 is a step of pre-cutting the bonding layer 3 and the adhesive film 4 in a predetermined pattern. The peeling step S04 is a step of peeling the unnecessary portion P of the bonding layer 3 and the adhesive film 4 from one surface of the substrate film 2.

In the cutting step S03, the bonding layer 3 and the adhesive film 4 are pre-cut so that the functional layer 11 has a circular shape in plan view of the substrate film 2. The bonding layer 3 and the adhesive film 4 are precut so that the protective layer 12 includes the straight line portion 13A extending along the extending direction of the substrate film 2, and the straight line portion 13B facing the circumference 11a of the functional layer 11, in plan view of the substrate film 2.

In the present embodiment, in the cutting step S03, the bonding layer 3 and the adhesive film 4 are pre-cut so that the protective layer 12 includes the island-shaped portion 21 having a triangular shape in plan view of the substrate film 2, the oblique side 21b of the island-shaped portion 21 faces the circumference 11a of the functional layer 11, and the base 21a of the island-shaped portion 21 faces the end part 2a of the substrate film 2 in the width direction.

In the peeling step S04, the unnecessary portion P of the bonding layer 3 and the adhesive film 4 is peeled by winding around a peel roll 37 as shown in FIG. 5. The separated unnecessary portion P is wound by a winding roll (not shown) in the stage after the peel roll 37. The unnecessary portion P is a portion of the bonding layer 3 and the adhesive film 4 on one surface of the substrate film 2, which does not include the functional layer 11 and the protective layer 12 that are finally formed. In the present embodiment, the unnecessary portion P is defined by the circumference 11a of the functional layer 11, the base 21 a and the oblique sides 21b, 21b of the island-shaped portion 21 of the protective layer 12, and the inner edge 22a of the belt-shaped portion 22 of the protective layer 12. The unnecessary portion P is connected in the extending direction of the substrate film 2, and can be continuously peeled from one surface of the substrate film 2 by winding around the peel roll 37. Thereafter, the bonding film 1 is wound around the winding roll to obtain the roll-shaped bonding film 1 shown in FIG. 1.

As described above, in the bonding film 1, the protective layer 12 includes the straight line portion 13A extending along the extending direction of the substrate film 2, and the straight line portion 13B facing the circumference 11a of the functional layer 11, in plan view of the substrate film 2. This configuration ensures that in comparison with a case where the protective layer 12 extends along the circumference 11a of the functional layer 11, the area of the unnecessary portion P of the bonding layer 3 and the adhesive film 4 can be secured, and the shape of the unnecessary portion can include straight line portions 13A, 13B. This enables equalization of a force affecting the unnecessary portion P in peeling from one surface of the substrate film 2, so that it is possible to suppress occurrence of defects such as breakage and chipping in the unnecessary portion P even when the unnecessary portion P is peeled while the bonding film 1 is wound at a constant conveyance rate. Since the bonding film 1 is continuously wound at a constant conveyance rate without occurrence of defects to improve production efficiency.

In the present embodiment, the protective layer 12 includes an island-shaped portion 21 having a triangular shape in plan view of the substrate film 2. The island-shaped portions 21 are arranged such that the oblique side 21b faces the circumference 11a of the functional layer 11, and the base 21a faces the end part 2a of the substrate film 2 in the width direction. This configuration enables the protective layers 12 to be efficiently arranged on the periphery of the functional layer 11. Therefore, the functional layer 11 can be firmly protected from a pressure in winding of the bonding film 1 in a roll shape, so that it is possible to suppress occurrence of deformation of the functional layer 11, transfer of winding impressions, and the like. In addition, the use of the straight line portions (base 21a and oblique sides 21b, 21b) of the island-shaped portions 21 enables the straight line portions 13A, 13B to be sufficiently formed in the shape of the unnecessary portion P of the bonding layer 3 and the adhesive film 4. This ensures that a force affecting the unnecessary portion P in peeling from one surface of the substrate film 2 can be more reliably equalized.

In the present embodiment, the protective layer 12 includes a belt-shaped portion 22 extending in the extending direction of the substrate film 2 at both end parts 2a, 2a of the substrate film 2 in the width direction. By arranging the protective layer 12 at both end parts 2a, 2a of the substrate film 2 in the width direction, the functional layer 11 can be more sufficiently protected from a pressure in winding of the bonding film 1 in a roll shape. In addition, using the straight line portion of the belt-shaped portion 22, the straight line portions 13A, 13B can be more sufficiently formed in the shape of the unnecessary portion P of the bonding layer 3 and the adhesive film 4. This ensures that a force affecting the unnecessary portion P in peeling from one surface of the substrate film 2 can be more reliably equalized.

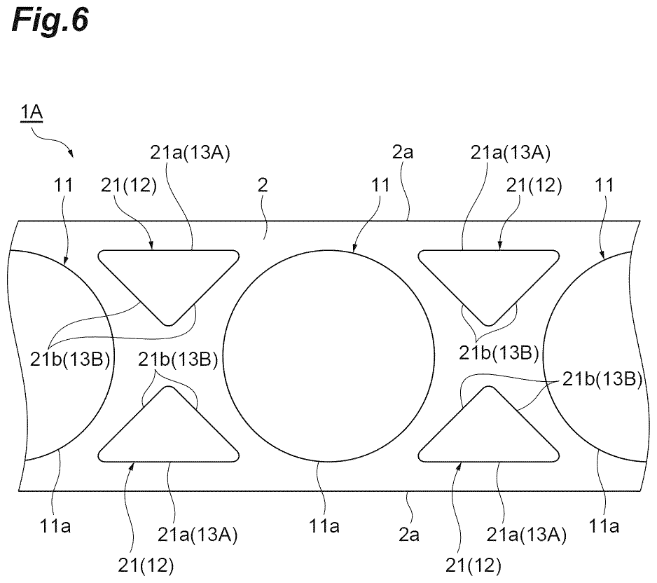

The present disclosure is not limited to the embodiment described above. For example, in the embodiment described above, the protective layer 12 includes the belt-shaped portion 22 extending in the extending direction of the substrate film 2, at both end parts 2a, 2a of the substrate film 2 in the width direction, but as in a bonding film 1A shown in FIG. 6, the belt-shaped portion 22 may be omitted, with only the triangular island-shaped portion 21 forming the protective layer 12. Even in the case of such a configuration, the same effect as in the embodiment described above can be exhibited. In addition, it is possible to secure the area of the unnecessary portion P of the bonding layer 3 and the adhesive film 4, which is larger by an amount corresponding to the belt-shaped portion 22 omitted. Therefore, a force affecting the unnecessary portion P in peeling from one surface of the substrate film 2 can be more reliably equalized.

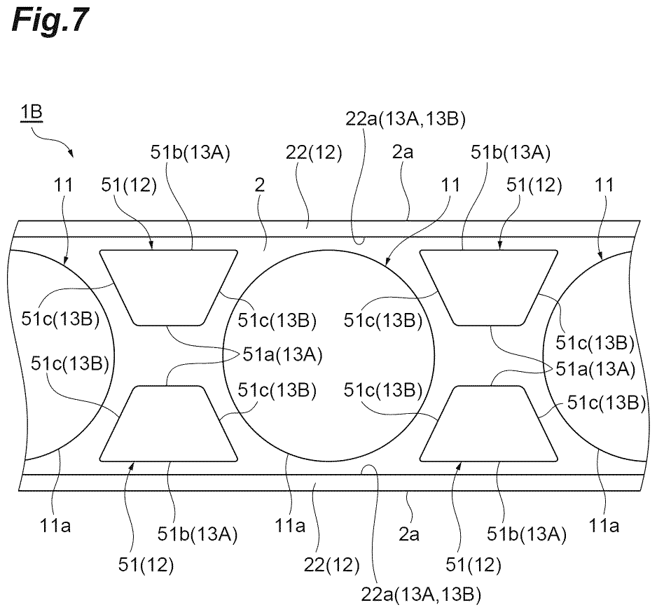

In the embodiment described above, the island-shaped portions 21 having a triangular shape in plan view of the substrate film 2 are arranged, but instead of the island-shaped portions 21, island-shaped portions 51 having a trapezoidal shape in plan view of the substrate film 2 may be arranged as in a bonding film 1B shown in FIG. 7. In the example of FIG. 7, the island-shaped portion 21 has an isosceles trapezoidal shape, and is arranged with its upper base 51a facing the center of the substrate film 2 in the width direction. The upper base 51a of the island-shaped portion 21 corresponds to the straight line portion 13A extending along the extending direction of the substrate film 2. A lower base 51b of the island-shaped portion 51 corresponds to the straight line portion 13A extending along the extending direction of the substrate film 2, and faces the end part 2a of the substrate film 2 in the width direction and an inner edge 22a of the belt-shaped portion 22. An oblique side 51c of the island-shaped portion 51 corresponds to the straight line portion 13B facing the circumference 11a of the functional layer 11.

Even in the case of such a configuration, the same effect as in the embodiment described above can be exhibited. In addition, since the island-shaped portion 51 has a trapezoidal shape, the straight line portions 13A can be sufficiently arranged, so that a force affecting the unnecessary portion P in peeling from one surface of the substrate film 2 can be more reliably equalized. In the configuration of FIG. 7, the belt-shaped portion 22 may be omitted as in FIG. 6.

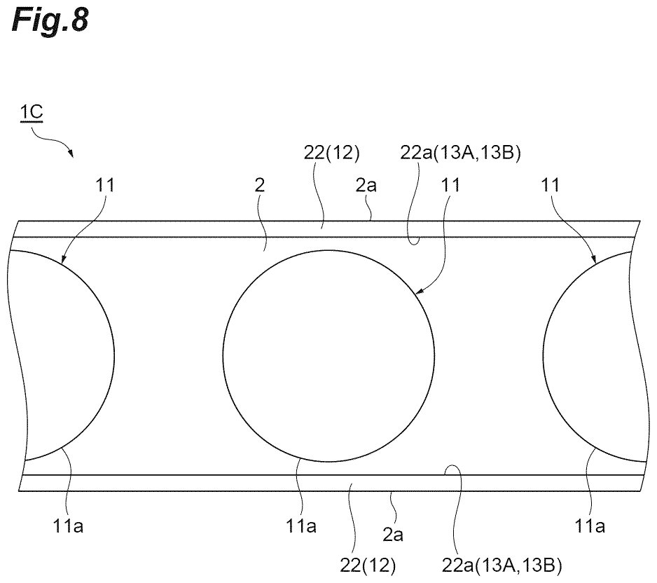

As in a bonding film 1C shown in FIG. 8, the island-shaped portion may be omitted, with only the belt-shaped portion 22 forming the protective layer 12. Even in the case of such a configuration, the same effect as in the embodiment described above can be exhibited. In addition, it is possible to secure the area of the unnecessary portion P of the bonding layer 3 and the adhesive film 4, which is larger by an amount corresponding to the island-shaped portion omitted. Therefore, a force affecting the unnecessary portion P in peeling from one surface of the substrate film 2 can be more reliably equalized. The omission of the island-shaped portion simplifies the pre-cutting pattern to improve the yield of the bonding film 1C.

### REFERENCE SIGNS LIST

1 Bonding film
2 Substrate film
2a End part
3 Bonding layer
4 Adhesive film
11 Functional layer
11a Circumference
12 Protective layer
13A, 13B Straight line portion
21 Island-shaped portion
21a Base
21b Oblique side
22 Belt-shaped portion
51 Island-shaped portion
51a Upper base
51b Lower base
51c Oblique side
P Unnecessary portion

1. A bonding film comprising:
a long substrate film; and
a bonding layer and an adhesive film provided on one surface of the substrate film, wherein one surface of the substrate film is provided with
a plurality of functional layers including the bonding layer and the adhesive film and arranged apart from one another in an extending direction of the substrate film, and
a plurality of protective layers including the bonding layer and the adhesive film and arranged symmetrically with respect to a width direction of the substrate film so as to surround the functional layers,
the functional layer has a circular shape in plan view of the substrate film, and
the protective layer includes a straight line portion extending along the extending direction of the substrate film, and a straight line portion facing a circumference of the functional layer, in plan view of the substrate film.

2. The bonding film according to claim 1, wherein the protective layer includes an island-shaped portion having a triangular shape in plan view of the substrate film, and is arranged such that an oblique side of the island-shaped portion faces the circumference of the functional layer and a base of the island-shaped portion faces an end part of the substrate film in the width direction.

3. The bonding film according to claim 1, wherein the protective layer includes an island-shaped portion having a trapezoidal shape in plan view of the substrate film, and is arranged such that an oblique side of the island-shaped portion faces the circumference of the functional layer and a lower base of the island-shaped portion faces an end part of the substrate film in the width direction.

4. The bonding film according to claim 1, wherein the protective layer includes a belt-shaped portion extending in the extending direction of the substrate film at both end parts of the substrate film in the width direction.

5. A method for producing a bonding film, comprising:
unwinding a long substrate film with a bonding layer provided on one surface thereof at a predetermined conveyance rate;
laminating an adhesive film to the bonding layer;
pre-cutting the bonding layer and the adhesive film in a predetermined pattern;
peeling an unnecessary portion of the bonding layer and the adhesive film from one surface of the substrate film, and forming, on one surface of the substrate film, a plurality of functional layers arranged apart from one another in an extending direction of the substrate film, and a plurality of protective layers arranged symmetrically with respect to a width direction of the substrate film so as to surround the functional layers; and
winding the bonding film obtained in the peeling in a roll shape,
wherein in the cutting, the bonding layer and the adhesive film are pre-cut so that the functional layer has a circular shape in plan view of the substrate film, and the protective layer includes a straight line portion extending along the extending direction of the substrate film and a straight line portion facing a circumference of the functional layer in plan view of the substrate film.

6. The method for producing a bonding film according to claim 5, wherein in the cutting, the bonding layer and the adhesive film are pre-cut so that the protective layer includes an island-shaped portion having a triangular shape in plan view of the substrate film, an oblique side of the island-shaped portion faces the circumference of the functional layer, and a base of the island-shaped portion faces an end part of the substrate film in the width direction.

7. The method for producing a bonding film according to claim 5, wherein in the cutting, the bonding layer and the adhesive film are pre-cut so that the protective layer includes an island-shaped portion having a trapezoidal shape in plan view of the substrate film, the oblique side of the island-shaped portion faces the circumference of the functional layer, and a lower base of the island-shaped portion faces an end part of the substrate film in the width direction.

8. The method for producing a bonding film according to claim 5, wherein in the cutting, the bonding layer and the adhesive film are pre-cut so that the protective layer includes a belt-shaped portion extending in the extending direction of the substrate film at both end parts of the substrate film in the width direction.
